(19) United States
(12) Patent Application Publication
(10) Pub. No.: US 2010/0055412 A1
(43) Pub. Date: Mar. 4, 2010

(54) String With Refractory Metal Core For String Ribbon Crystal Growth

(75) Inventors: Christine Richardson, Northborough, MA (US); Lawrence Felton, Hopkinton, MA (US)

Correspondence Address: Sunstein Kann Murphy & Timbers LLP, 125 SUMMER STREET, BOSTON, MA, 02110-1618, US

(73) Assignee: EVERGREEN SOLAR, INC., Marlborough, MA (US)

(21) Appl. No.: 12/553,252

(22) Filed: Sep. 3, 2009

Related U.S. Application Data
(60) Provisional application No. 61/093,946, filed on Sep. 3, 2008.

(51) Int. Cl. C01B 31/36; C23C 16/22; B32B 3/02; C30B 15/00; C01B 33/00

(52) U.S. Cl. 428/192; 427/419.7; 427/249.3; 117/24

(57) ABSTRACT

A method of forming a string for use in a string ribbon crystal provides a refractory metal as a core for the string and forms a first layer of material on the core. A method of growing a ribbon crystal provides a pair of strings. Each string has a refractory metal core. The method further passes the strings through a molten material to grow the ribbon crystal between the pair of strings.

A ribbon crystal wafer includes a ribbon crystal material and a pair of strings in the ribbon crystal material. Each string defines an outer edge of the wafer, and each string includes a refractory metal core.

### CROSS REFERENCE TO RELATED APPLICATIONS

The present application claims priority to U.S. Provisional Patent Application No. 61/093,946 filed Sep. 3, 2008, the disclosure of which is incorporated by reference herein in its entirety.

### FIELD OF THE INVENTION

The invention generally relates to ribbon crystals and, more particularly, the invention relates to string used to form the ribbon crystals.

### BACKGROUND OF THE INVENTION

Solar cells may be formed from silicon wafers fabricated by a “ribbon pulling” technique. The ribbon pulling technique generally uses a crystal growth system that includes a specialized furnace surrounding a crucible containing molten silicon. During the growth process, two strings are typically passed through the crucible so that molten silicon solidifies onto its surface, thus forming a growing ribbon crystal between the two strings. Two or more ribbon crystals may be formed at the same time by passing multiple sets of strings through the crucible.

The composition and structure of the strings can affect the properties of the resultant ribbon crystal, which may impact the performance of devices made with such ribbon crystals, e.g., the conversion efficiency of a solar cell. The composition and structure of the string can also affect the manufacturing process, which may impact the cost of forming the ribbon crystal. For example, string formed of brittle materials may cause the string to break during the ribbon crystal growth process, causing reduced yields and unnecessary downtime during the manufacturing process. Similarly, manufacturing inefficiencies may also result when the string material and the melt material have large differences in coefficients of thermal expansion, which may result in breakage at the interface between the string and the ribbon crystal during the cooling process.

### SUMMARY OF THE INVENTION

In accordance with one embodiment of the invention, a method of forming a string for use in a string ribbon crystal provides a refractory metal as a core for the string and forms a first layer of material on the core.

In accordance with another embodiment of the invention, a method of growing a ribbon crystal provides a pair of strings. Each string has a refractory metal core. The method also passes the strings through a molten material to grow the ribbon crystal between the pair of strings. Each string may have a first layer formed on the refractory metal core.

In accordance with another embodiment of the invention, a ribbon crystal wafer includes a ribbon crystal material and a pair of strings in the ribbon crystal material. Each string defines an outer edge of the wafer, and each string includes a refractory metal core. The string may have a first layer and a second layer.

In related embodiments, the method may further form a second layer of material on the first layer. The first layer may include silicon carbide and/or the second layer may include carbon. Forming may include a chemical vapor deposition process. Forming may include forming the first layer in a molten material that substantially forms the string ribbon crystal. Passing the strings through the molten material may further include forming a first layer on the refractory metal core in the molten material. The refractory metal may include titanium, vanadium, nickel, chromium, tantalum, niobium, tungsten, molybdenum, rhenium, or alloys thereof.

### BRIEF DESCRIPTION OF THE DRAWINGS

The foregoing and advantages of the invention will be appreciated more fully from the following further description thereof with reference to the accompanying drawings wherein:

FIG. 1 schematically shows a perspective view of a ribbon crystal growth system that may use a string configured according to embodiments of the present invention;

FIG. 2 schematically shows a partially cut away view of the ribbon crystal growth system shown in FIG. 1 with part of the housing removed;

FIG. 3 shows a process of forming a string ribbon crystal using strings configured according to embodiments of the present invention;

FIG. 4 schematically shows a perspective view of a string formed according to embodiments of the present invention;

FIG. 5 schematically shows a cross-sectional view of the string along line A-A of FIG. 4;

FIG. 6 schematically shows a perspective view of a string formed according to embodiments of the present invention;

FIG. 7 schematically shows a cross-sectional view of the string along line B-B of FIG. 6; and

FIG. 8 schematically shows a ribbon crystal wafer that may be formed from strings configured according to embodiments of the present invention.

### DESCRIPTION OF ILLUSTRATIVE EMBODIMENTS

Various embodiments of the present invention provide a string with a refractory metal core that may be used to grow a ribbon crystal. The string may also include one or more layers formed on the refractory metal core, formed either before or during the ribbon crystal growth process. A refractory metal core allows the string to be produced more easily and into longer lengths than would be possible with conventional prior art materials and processes.

Using a refractory metal material was initially not considered to be a viable option for replacing the core material in the string. This is primarily due to the fact that refractory metal materials act as contaminants in the ribbon crystal, and care is usually taken throughout the process to reduce the amount of contaminants that are present in the ribbon crystal. Contaminants may detrimentally affect the properties of the ribbon crystal, which may impact the performance of devices made with such ribbon crystals. It was surprisingly found, however, that the refractory metal contaminant level within the ribbon crystal was insubstantial, so it did not detrimentally impact the composition of the melt material. Details of illustrative embodiments are discussed below.

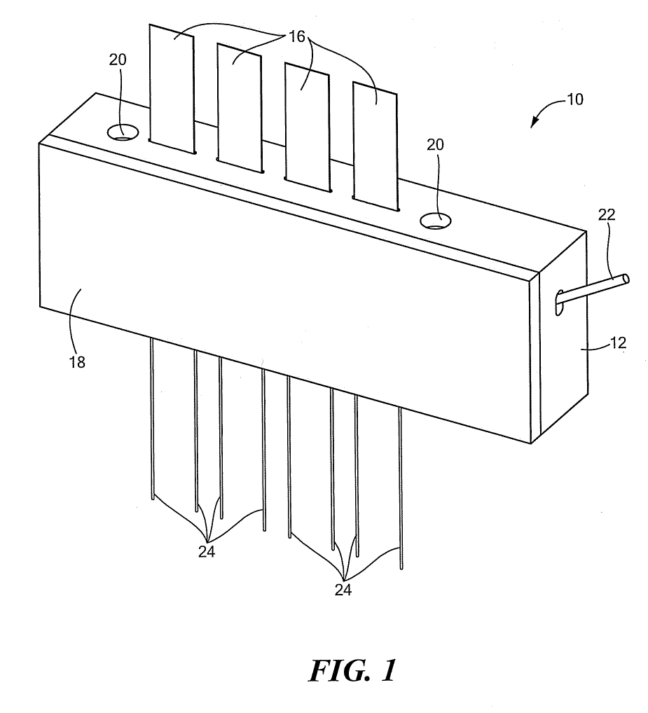

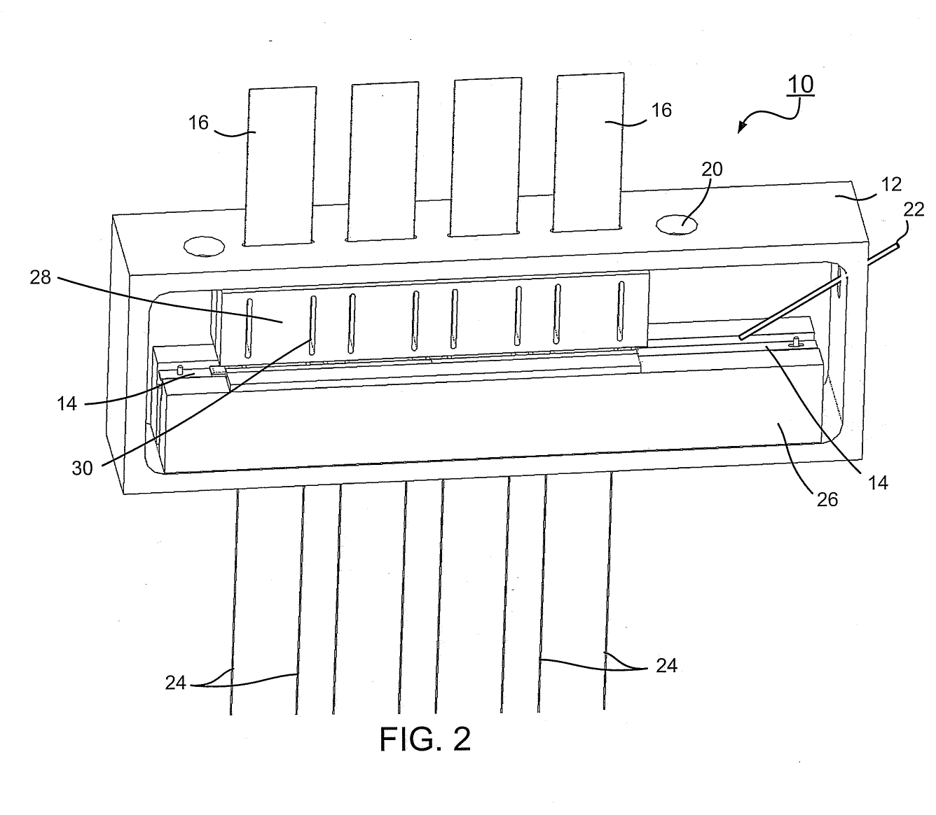

FIG. 1 schematically shows a ribbon crystal growth system 10 that may use a string formed according to embodiments of the present invention. The growth system 10 includes a housing 12 forming an enclosed or sealed interior. The interior may be substantially free of oxygen (e.g., to prevent combustion) and may include one or more gases, such as argon or other inert gas, that may be provided from an external gas source. The interior includes a crucible 14 (as shown in FIG. 2) and other components for substantially simultaneously growing a plurality of ribbon crystals 16.

Although FIG. 1 shows four ribbon crystals, the growth system 10 may substantially simultaneously grow one or more of the ribbon crystals. The ribbon crystals 16 may be formed from a wide variety of materials depending on the application. For example, the ribbon crystal 16 may be single crystal or polycrystalline silicon or other silicon-based materials (e.g., silicon germanium) when used for photovoltaic applications. Other materials may include gallium arsenide or indium phosphide. Thus, the following discussion of silicon ribbon crystals 16 is illustrative and not intended to limit all embodiments of the invention. The housing 12 may include a door 18 to allow inspection of the interior and its components and one or more optional windows 20. The housing 12 may also have an opening for a feed inlet 22. The feed inlet 22 allows feedstock material to be directed into the interior of the housing 12 to the crucible 14 to be melted.

FIG. 2 schematically shows a partially cut away view of the growth system 10 shown in FIG. 1 with a part of the housing 12 removed. As shown, the growth system 10 includes a crucible 14 for containing molten material (not shown) in the interior of the housing 12. In one embodiment, the crucible 14 may have a substantially flat top surface that may support or contain the molten material. The crucible 14 may include string holes (not shown) that allow strings 24 to pass through the crucible 14.

The growth system 10 also includes insulation that is configured based upon the thermal requirements of the regions in the housing 12, e.g., the region containing the molten material and the region containing the resulting growing ribbon crystal 16. As such, the insulation includes a base insulation 26 that forms an area containing the crucible 14 and the molten material, and an afterheater 28 positioned above the base insulation 26 (from the perspective of the drawings). The afterheater 28 may be supported by the base insulation 26, e.g., by posts (not shown). In addition, or alternatively, the afterheater 28 may be attached or secured to a top portion of the housing 12. The afterheater 28 may have two portions which are positioned on either side of the growing ribbon crystals 16. The two portions may form one or more channels through which the ribbon crystal 16 grows. The afterheater 28 provides a controlled thermal environment that allows the growing ribbon crystal 16 to cool as it rises from the crucible 14. In some embodiments, the afterheater 28 may have one or more additional openings or slots 30 within the afterheater 28 for controllably venting heat from the growing ribbon crystals 16 as it passes through the inner surface of the afterheater 28.

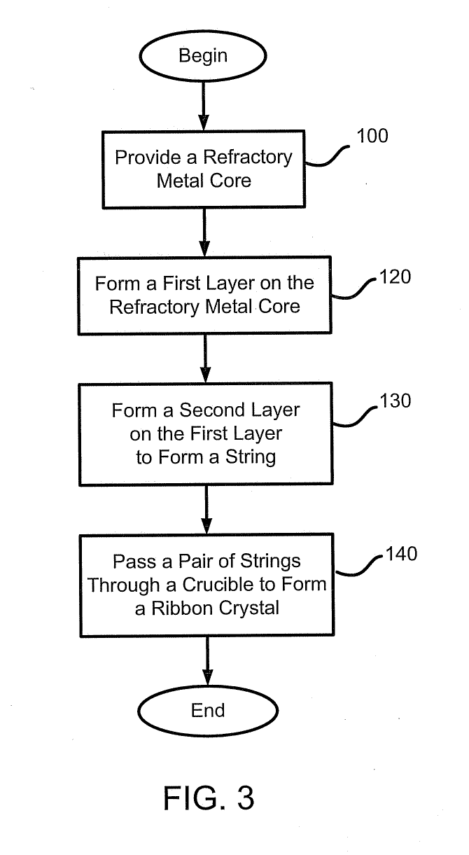

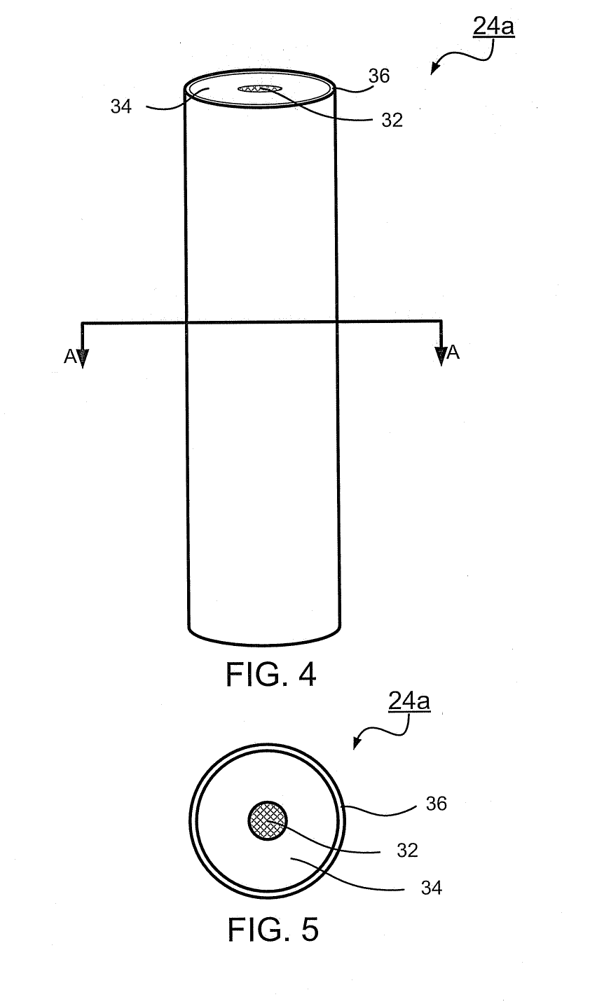

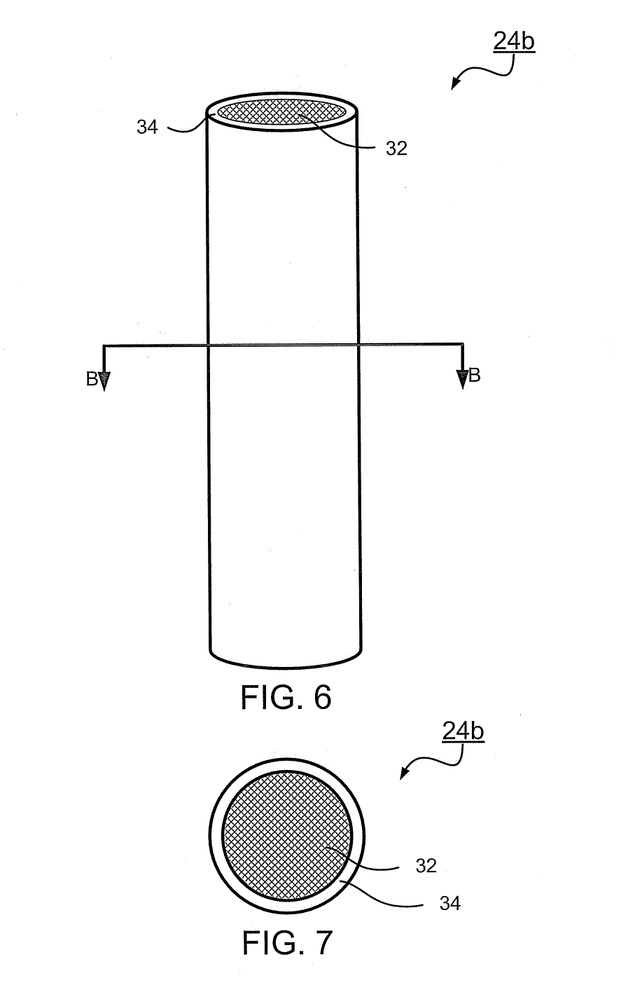

FIG. 3 shows a process of forming a string ribbon crystal using strings configured according to embodiments of the present invention. FIGS. 4 and 5 schematically show a perspective view and a cross-sectional view of an illustrative string, and FIGS. 6 and 7 schematically show a perspective view and a cross-sectional view of another illustrative string. Although the following discussion describes various relevant steps of forming the string and the string ribbon crystal, it may not describe all the required steps. Other processing steps may also be performed before, during, and/or after the discussed steps. Such steps, if performed, have been omitted for simplicity. The order of the processing steps may also be varied and/or combined. Accordingly, some steps are not described and shown.

The process begins at step 100, which provides a refractory metal core 32 for the string 24. The refractory metal core 32 is formed with a refractory metal material. As defined herein, a refractory metal is a material that has a melting temperature of about 1200° C. or higher, such as titanium, vanadium, nickel, chromium, tantalum, niobium, tungsten, molybdenum, rhenium, or alloys thereof. For example, the refractory metal material should be able to sufficiently withstand the high temperatures of the melt. The refractory metal core 32 may be fabricated by known forming processes, such as wire drawing or extrusion. One of the benefits of using a refractory metal is its ease of manufacturing, which can subsequently improve the manufacturability of the string itself. For example, embodiments of the present invention may allow the string to be formed into longer lengths than previously provided with prior art processes.

For instance, in current string forming processes, the material typically used to form the string core is carbon. Carbon is relatively difficult to handle and tends to break due to its brittle nature. This results in shorter lengths for the core material, and thus the string, which translates into reduced yields for the ribbon growth process. For example, the string manufacturing process would need to be more frequently interrupted in order to introduce the new core into the system. In addition, the standard carbon core is typically more difficult to make than embodiments of the present invention (e.g., metal forming processes, such as extrusion). This may further lead to manufacturing variations and increased production costs. For example, the carbon core is typically a monofilament fiber that is formed with standard ceramic forming processes. These processes typically entail numerous steps, such as a spinning step to form the material into the desired shape, an oxidation step to stabilize the material, and a carbonization step to leave a substantially carbon fiber, which may also introduce dimensional variations to the string's core.

In contrast, embodiments of the present invention use metal forming processes, such as extrusion, which allow the core to be produced more easily, more repeatably with less dimensional variations, and into longer lengths than would be possible with the prior art materials and processes. The refractory metal core 32 may be formed into a substantially cylindrical shape having any desired diameter and length. For example, in a string having a diameter of about 150 μm or so, the refractory metal core 32 may be about 10 μm to about 30 μm in one embodiment, and may be about 80 μm to about 130 μm in another embodiment, although other diameters may be used.

In step 120, a first layer 34 is formed on the refractory metal core 32. The first layer 34 may be formed from a material with a similar coefficient of thermal expansion as the melt material. For example, when silicon is the melt material, the first layer 34 may be silicon carbide, such as a carbon-rich silicon carbide. The first layer 34 may be formed on the refractory metal core 32 before entering the melt by any known forming process. For example, the first layer 34 may be formed on the refractory metal core 32 using a chemical vapor deposition process. Alternatively, the first layer 34 may be formed in the melt material when the refractory metal core 32 contacts the melt material. The melt material may react with or diffuse into the refractory metal core 32 forming the first layer 34. For example, when tungsten is the refractory metal core material and silicon is the melt material, the first layer 34 may be formed from tungsten silicide. The first layer 34 may have any desired thickness. For example, in a string having a diameter of about 150 μm or so, and the first layer 34 formed on the refractory metal core 32 before entering the melt, the refractory metal core 32 may be about 10 μm to about 30 μm and the first layer 34 may be about 60 μm to about 70 μm, although other thicknesses may be used. Similarly, in a string having a diameter of about 150 μm or so, and the first layer 34 formed on the refractory metal core 32 in the melt material, the refractory metal core 32 may be about 80 μm to about 130 μm and the first layer 34 may be about 20 μm to about 70 μm, although other thicknesses may be used. FIGS. 4 and 5 schematically show an illustrative string 24a when the first layer 34 is formed before entering the melt, and FIGS. 6 and 7 schematically show an illustrative string 24b when the first layer 34 is formed in the melt, although the various elements are not drawn to scale.

In step 130, an optional second layer 36 may be formed on the first layer 34 when the first layer 34 is formed before entering the melt. The second layer 36 may be formed of a material that wets well to the melt material, but is thin enough that it does not substantially affect the coefficient of thermal expansion properties between the first layer 34 and the melt material. For example, when silicon is the melt material, the second layer 36 may be a carbon layer that, preferably, is about a few microns in thickness. The second layer 36 may be formed on the first layer 32 by any known forming process. For example, the second layer 36 may be formed on the first layer 34 using a chemical vapor deposition process.

Although one or two layers are discussed above, additional layers may be formed on the refractory metal core 32 depending on the application in embodiments where the first layer 34 is formed before entering the melt. In addition, other shapes and configurations may be used for the refractory metal core 32, the layers 34, 36, and/or the string 24, e.g., as disclosed in U.S. patent application Ser. No. 12/200,996, entitled Reduced Wetting String for Ribbon Crystal, U.S. patent application Ser. No. 12/201,117, entitled Ribbon Crystal String for Increasing Wafer Yield, and U.S. patent application Ser. No. 12/201,180, entitled Ribbon Crystal String with Extruded Refractory Material, all filed on Aug. 29, 2008, the disclosures of which are incorporated herein by reference in their entirety.

Once string 24 is formed, two or more strings 24 are passed through the crucible 14 at a rate as to allow the molten material to solidify onto its surface, thus forming the growing ribbon crystal 16 between the two strings 24 (step 140). Two or more ribbon crystals may be formed at the same time by passing multiple sets of strings 24 through the crucible 14. For example, the crucible 14 may have an elongated shape with a region for growing ribbon crystals 16 in a side-by-side arrangement along its length, as shown in FIGS. 1 and 2. The strings 24 with the ribbon crystal attached are passed through the afterheater 28 so that the ribbon crystal 16 may cool in a controlled environment. The ribbon crystal 16 is then removed from the housing 12 enclosing the specialized furnace.

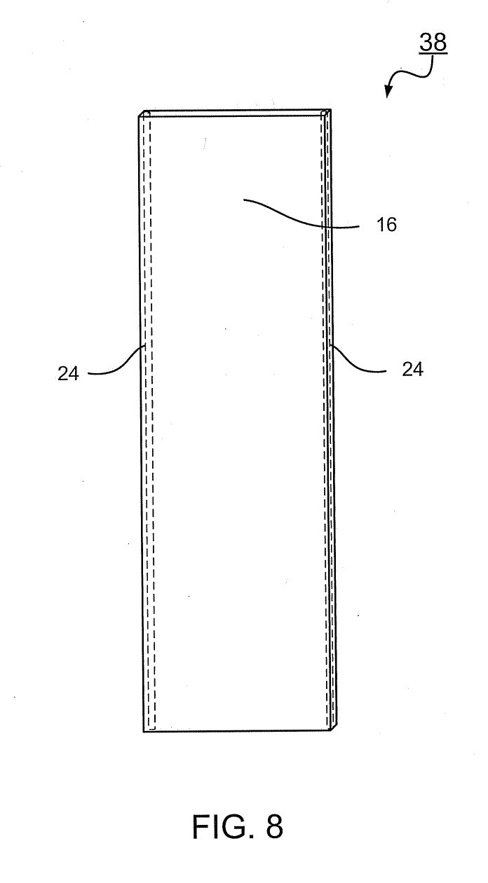

After the ribbon crystals 16 are pulled out of the housing 12, they may be cut into strips or wafers 38 of desired length, such as shown in FIG. 8. For example, the wafer 38 may have a generally rectangular shape and a relatively large surface area on its front and back faces. For instance, the wafer 38 may have a width of about 3 inches, and a length of about 6 inches, although the length may vary significantly. For example, in some known processes, the length depends upon a furnace operator's discretion as to where to cut the ribbon crystal 16 as it grows. In addition, the width can vary depending upon the separation of its two strings 24 that form the ribbon crystal width boundaries. Accordingly, discussion of specific lengths and widths are illustrative and not intended to limit various embodiments of the present invention. Also, the elements shown in FIG. 8 are not drawn to scale. For example, the string 24 shown in FIG. 8 defines the outer edge of the wafer.

The ribbon crystals 16 may be cut using a laser cutting process, as is well known to those skilled in the art. The resulting wafer 38 may then be subjected to additional processes depending on its application. For example, in photovoltaic applications, the wafer 38 may be subjected to a texturing process in order improve the conversion efficiencies of the wafer 38. The wafer 38 may also be subjected to a metal etch process in order to clean off any surface contaminants that may inadvertently get incorporated into the wafer in subsequent processes. The wafer 38 may also be subjected to a deposition process (e.g., an n-type or p-type material deposited onto the wafer) and a high temperature diffusion process in order to drive the n-type or p-type material into the wafer 38.

Throughout the manufacturing process, there was a concern that the refractory metal core material would be introduced into the ribbon crystal 16 or wafer 28 at various times and contaminate it. For example, if the string broke while in the melt, the exposed refractory metal material could be incorporated into the melt material. Similarly, during the laser cutting process, the exposed refractory metal material could get incorporated into the wafer during the cutting process or the subsequent high temperature diffusion process. Surprisingly, however, the refractory metal material did not get incorporated into the ribbon crystal or wafer in any significant amount. Although the reasons behind this surprising result are not fully understood, it is believed that any exposed refractory metal material forms a protective layer with the melt or the ribbon crystal material. For example, if the refractory metal core material is tungsten and the ribbon crystal material is silicon, the exposed refractory metal core material may form a tungsten silicide, which is not incorporated into the ribbon crystal or wafer materials. Thus, it was realized that the process of forming the first layer 34 on the refractory metal core 32 may occur before the refractory metal core 32 enters the melt or while the refractory metal core 32 is in the melt.

Although the above discussion discloses various exemplary embodiments of the invention, it should be apparent that those skilled in the art can make various modifications that will achieve some of the advantages of the invention without departing from the true scope of the invention.

What is claimed is:

1. A method of forming a string for use in a string ribbon crystal, the method comprising:
providing a refractory metal as a core for the string; and
forming a first layer of material on the core.

2. The method of claim 1, wherein the first layer includes silicon carbide.

3. The method of claim 1, further comprising:
forming a second layer of material on the first layer.

4. The method of claim 3, wherein the first layer includes silicon carbide and the second layer includes carbon.

5. The method of claim 1, wherein forming includes a chemical vapor deposition process.

6. The method of claim 1, wherein forming includes forming the first layer in a molten material that substantially forms the string ribbon crystal.

7. The method of claim 1, wherein the refractory metal includes titanium, vanadium, nickel, chromium, tantalum, niobium, tungsten, molybdenum, rhenium, or alloys thereof.

8. A method of growing a ribbon crystal, the method comprising:
providing a pair of strings, each string comprising a refractory metal core; and
passing the strings through a molten material to grow the ribbon crystal between the pair of strings.

9. The method of claim 8, wherein each string further comprises a first layer formed on the refractory metal core.

10. The method of claim 9, wherein the first layer includes silicon carbide.

11. The method of claim 9, wherein each string further comprises a second layer formed on the first layer.

12. The method of claim 11, wherein the first layer includes silicon carbide and the second layer includes carbon.

13. The method of claim 8, wherein passing the strings through the molten material further includes forming a first layer on the refractory metal core in the molten material.

14. The method of claim 8, wherein the refractory metal includes titanium, vanadium, nickel, chromium, tantalum, niobium, tungsten, molybdenum, rhenium, or alloys thereof.

15. A ribbon crystal wafer comprising:
a ribbon crystal material; and
a pair of strings in the ribbon crystal material, each string defining an outer edge of the wafer, each string comprising a refractory metal core.

16. A ribbon crystal wafer of claim 15, wherein each string further comprises a first layer formed on the refractory metal core.

17. A ribbon crystal wafer of claim 16, wherein the first layer includes silicon carbide.

18. A ribbon crystal wafer of claim 16, wherein each string further comprises a second layer formed on the first layer.

19. A ribbon crystal wafer of claim 18, wherein the first layer includes silicon carbide and the second layer includes carbon.

20. A ribbon crystal wafer of claim 15, wherein the refractory metal includes titanium, vanadium, nickel, chromium, tantalum, niobium, tungsten, molybdenum, rhenium, or alloys thereof.
